(19) United States
(12) Patent Application Publication
(10) Pub. No.: US 2025/0201772 A1
(43) Pub. Date: Jun. 19, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 18/583,124

(22) Filed: Feb. 21, 2024

(30) Foreign Application Priority Data
Dec. 18, 2023 (KR) 10-2023-0184746

(51) Int. Cl. H01L 25/065; H01L 21/20; H01L 21/66; H01L 23/00

(52) U.S. Cl. CPC H01L 25/0655; H01L 21/2007; H01L 22/14; H01L 24/05; H01L 24/29; H01L 2224/05025; H01L 2224/05147; H01L 2224/05184; H01L 2224/29005; H01L 2224/29025; H01L 2924/01029; H01L 2924/01074; H01L 2924/1431; H01L 2924/1434

(57) ABSTRACT

A semiconductor device may include a substrate including a chip region and a pad region, first bonding pads positioned in the chip region, second bonding pads positioned on the first bonding pads and having a front surface connected to the first bonding pads, a first probing pad positioned in the pad region, extending to the chip region, and connected to a rear surface of at least one second bonding pad among the second bonding pads, and a second probing pad positioned neighbor the first probing pad and connected to the rear surface of at least one second bonding pad among the second bonding pads.

### CROSS-REFERENCE TO RELATED APPLICATION

This application claims priority under 35 U.S.C. § 119 to Korean Patent Application No. 10-2023-0184746 filed on Dec. 18, 2023, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, a semiconductor device in which a memory cell is formed as a single layer on a substrate has reached limit in its integration degree. Therefore, a three-dimensional semiconductor device in which memory cells are stacked on a substrate has been developed. In addition, various structures and manufacturing methods are being developed in order to improve operation reliability of the semiconductor device.

### SUMMARY

According to an embodiment of the present disclosure, a semiconductor device may include a substrate including a chip region and a pad region, first bonding pads positioned in the chip region, second bonding pads positioned on the first bonding pads and having a front surface connected to the first bonding pads, a first probing pad positioned in the pad region, extending to the chip region, and connected to a rear surface of at least one second bonding pad among the second bonding pads, and a second probing pad positioned neighbor the first probing pad and connected to the rear surface of at least one second bonding pad among the second bonding pads.

According to an embodiment of the present disclosure, a semiconductor device may include a first test structure including a first lower bonding pad and a first upper bonding pad electrically connected to the first lower bonding pad, a second test structure including a second lower bonding pad and a second upper bonding pad electrically connected to the second lower bonding pad, and positioned neighbor the first test structure in a first direction, a first probing pad electrically connected to the first test structure and extending in the first direction, and a second probing pad electrically connected to the second test structure and extending in the first direction.

According to an embodiment of the present disclosure, a method of manufacturing a semiconductor device may include forming a first wafer including a first substrate and first bonding pads, forming a second wafer including a second substrate and second bonding pads, bonding the first wafer and the second wafer so that a front surface of the first bonding pads and a front surface of the second bonding pads are connected, forming probing pads respectively connected to rear surfaces of the second bonding pads, and detecting a bonding defect by applying different voltages to a pair of probing pads among the probing pads.

These and other features and advantages of the present invention will become apparent from the following figures and detailed description of example embodiments of the present invention.

### BRIEF DESCRIPTION OF THE DRAWINGS

FIGS. 1A to 1C simplified diagrams illustrating a semiconductor device according to an embodiment of the present disclosure.

FIGS. 2A to 2C simplified diagrams illustrating a semiconductor device according to an embodiment of the present disclosure.

FIGS. 3A to 5C simplified diagrams illustrating a method of manufacturing a semiconductor device according to an embodiment of the present disclosure.

### DETAILED DESCRIPTION

Various embodiments of the present invention disclosure provide a semiconductor device and a method of manufacturing the semiconductor device having a stable structure and improved performance characteristics.

According to the present invention, a semiconductor device having a stable structure and improved reliability may be provided.

Hereinafter, example embodiments according to the present invention are described with reference to the accompanying drawings.

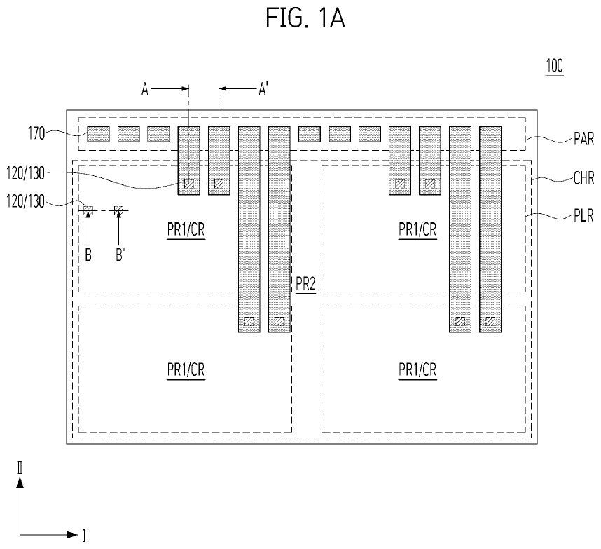

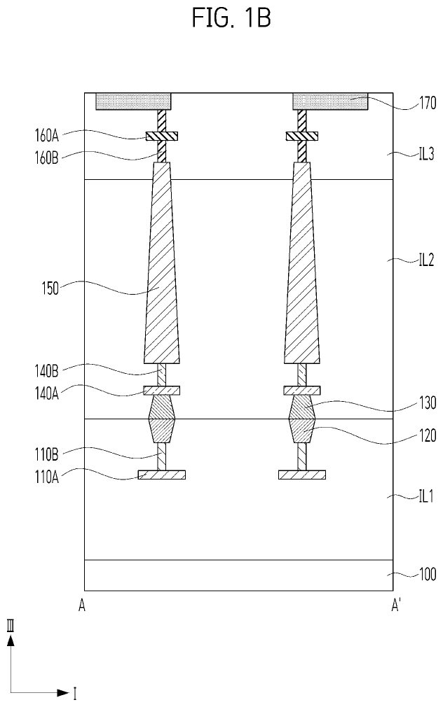

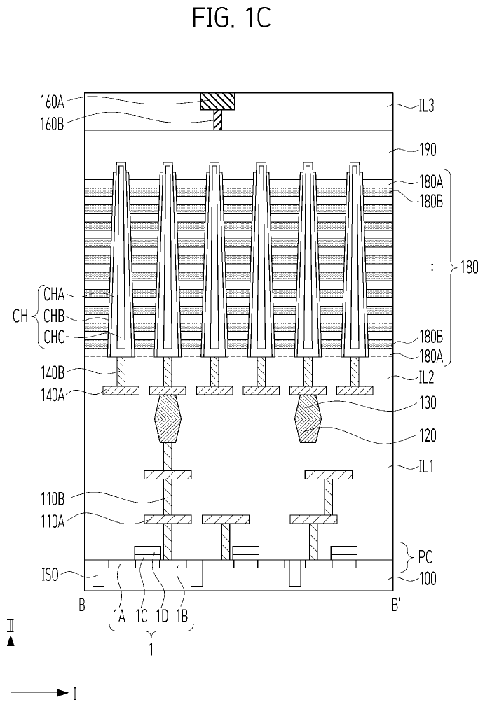

FIGS. 1A to 1C are simplified diagrams illustrating a semiconductor device according to an embodiment of the present invention disclosure. FIG. 1A is a plan view, FIG. 1B may be a cross-sectional view taken along A-A′ of FIG. 1A, and FIG. 1C may be a cross-sectional view taken along B-B′ of FIG. 1A.

Referring to FIGS. 1A to 1C, the semiconductor device may include at least one of a substrate 100, a first interlayer insulating layer IL1, a second interlayer insulating layer IL2, a third interlayer insulating layer IL3, a gate structure 180, channel structures CH, first bonding pads 120, second bonding pads 130, probing pads 170, and test patterns. The semiconductor device may further include first lines 110A, first contact vias 110B, second lines 140A, second contact vias 140B, third lines 160A, third contact vias 160B, contact plugs 150, and a source structure 190.

The substrate 100 may include a chip region CHR and a pad region PAR. The chip region CHR may include plain regions PLR. Each of the plane regions PLR may include a first peripheral circuit region PR1 and a cell region CR. The first peripheral circuit region PR1 and the cell region CR may be stacked. A second peripheral circuit region PR2 may be positioned between the plane regions PLR.

A peripheral circuit PC may be positioned in the first peripheral circuit region PR1. The peripheral circuit PC may include at least one of a page buffer and a decoder. Alternatively, the peripheral circuit PC may include a transistor 1. The transistor 1 may include junctions 1A and 1B, a gate electrode 1D, and a gate insulating layer 1C.

For example, the gate insulating layer 1C may be positioned between a gate electrode 1D and the substrate 100. The peripheral circuit PC may further include at least one of a page buffer and a decoder. The gate structure 180 may be positioned in the cell region CR. The gate structure 180 may be formed between the second and third interlayer insulating layers IL2 and IL3.

In addition, channel structures CH extending through the gate structure 180 and connected to the peripheral circuit PC may be positioned in the cell region CR. Probing pads 170 may be positioned in the pad region PAR. For example, the probing pads 170 may be for detecting a bonding defect.

First bonding pads 120 may be positioned over or on the substrate 100 in the first interlayer insulating layer IL1. The first bonding pads 120 may be positioned in the chip region CHR of the substrate 100. For example, the first bonding pads 120 may be positioned in at least one of the first peripheral circuit region PR1, the second peripheral circuit region PR2, and the cell region CR. The first bonding pads 120 may be positioned in the first interlayer insulating layer IL1. For example, the first interlayer insulating layer IL1 may be positioned on the substrate 100. The first bonding pads 120 may be connected to the first lines 110A. The first lines 110A and the first bonding pads 120 may be connected through the first contact vias 110B. In addition, at least one of the first contact vias 110B may connect the first line 110A and the peripheral circuit PC. The first lines 110A and the first contact vias 110B may be positioned in the first interlayer insulating layer IL1. The first bonding pads 120 may include a conductive material such as copper or tungsten. In an embodiment, for example, the first bonding pads 120 may include copper. The first lines 110A and the first contact vias 110B may include a conductive material such as tungsten. The first interlayer insulating layer IL1 may include an insulating material such as oxide.

The second bonding pads 130 may be positioned on the first bonding pads 120 and may be in direct contact with the first bonding pads 120. The second bonding pads 130 may be positioned in the second interlayer insulating layer IL2. For example, the second interlayer insulating layer IL2 may be positioned on the first interlayer insulating layer IL1. The second bonding pads 130 may be bonded and connected to the first bonding pads 120. For example, a front surface of the second bonding pads 130 may be connected to a front surface of the first bonding pads 120. The second bonding pads 130 may include a conductive material such as copper or tungsten. In an embodiment, for example, the second bonding pads 130 may include copper.

The contact plugs 150 may be positioned over the second bonding pads 130. The contact plugs 150 may extend to the third interlayer insulating layer IL3 through the second interlayer insulating layer IL2. For example, the third interlayer insulating layer IL3 may be positioned on the second interlayer insulating layer IL2. The contact plugs 150 may be connected to the second lines 140A. The contact plugs 150 and the second lines 140A may be connected through the second contact vias 140B. The second lines 140A and the second contact vias 140B may be positioned in the second interlayer insulating layer IL2. The contact plugs 150, the second lines 140A, and the second contact vias 140B may include a conductive material such as tungsten.

The channel structures CH may be positioned over the second bonding pads 130. The channel structures CH and the second bonding pads 130 may be connected through the second lines 140A and the second contact vias 140B. The channel structures CH may extend through the gate structure 180 including alternately stacked insulating layers 180A and conductive layers 180B. The channel structures CH may extend into the source structure 190 through the gate structure 180. For example, the source structure 190 may be positioned on the gate structure 180. Each of the channel structures CH may include at least one of a channel layer CHA, a memory layer CHB surrounding the channel layer CHA, and an insulating core CHC in the channel layer CHA.

The probing pads 170 may be positioned in the pad region PAR. At least one of the probing pads 170 may extend from the pad region PAR to the chip region CHR. For example, at least one of the probing pads 170 may extend from the pad region PAR to the chip region CHR and may be connected to a rear surface of at least one second bonding pad 130 among the second bonding pads 130. The probing pad 170 and the second bonding pad 130 may be connected through the third line 160A, the third contact via 160B, and the contact structure 150. For example, the third lines 160A and the third contact vias 160B may be positioned on the contact structure 150 and may be positioned in the third interlayer insulating layer IL3.

In a process of bonding the first bonding pads 120 and the second bonding pads 130 or in a subsequent process, the first bonding pads 120 and the second bonding pads 130 may be deteriorated. For example, a delamination phenomenon may occur between the first bonding pads 120 and the second bonding pads 130, and copper migration may occur between delaminated positions. Therefore, detecting whether a bonding defect exists by monitoring whether the first bonding pads 120 and the second bonding pads 130 are deteriorated for each step is required.

According to an embodiment of the present disclosure, the probing pads 170 may be electrically connected to the bonding pads 120 and 130. A bonding defect may be detected by applying different voltages to a pair of probing pads 170 among the bonding pads 120 and 130 connected to the bonding pads 120 and 130. For example, a pair of probing pads 170 may be adjacent to and neighbor each other. For example, the pair of probing pads 170 may be positioned adjacent to each other in a first direction I. Alternatively, at least one probing pad 170 that is not connected to the bonding pads 120 and 130 may be positioned between the pair of probing pads 170. Manufacturing cost may be reduced by not performing subsequent processes when a bonding defect is detected.

According to the structure described above, in the semiconductor device, the bonding pads 120 and 130 may be positioned in the chip region CHR. In addition, in the semiconductor device, the probing pads 170 may be positioned in the pad region PAR. By applying different voltages to at least one pair of probing pads 170 among the probing pads 170, whether a bonding defect exists between the bonding pads 120 and 130 may be detected. Therefore, when a defect exists in bonding, manufacturing cost may be reduced by discarding a subsequent process without proceeding the subsequent process.

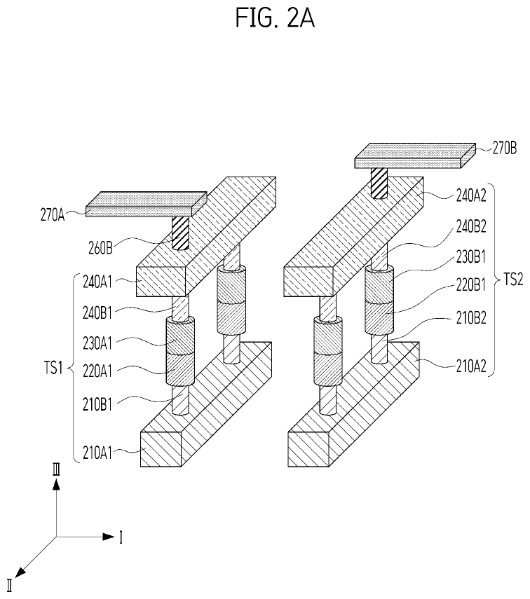

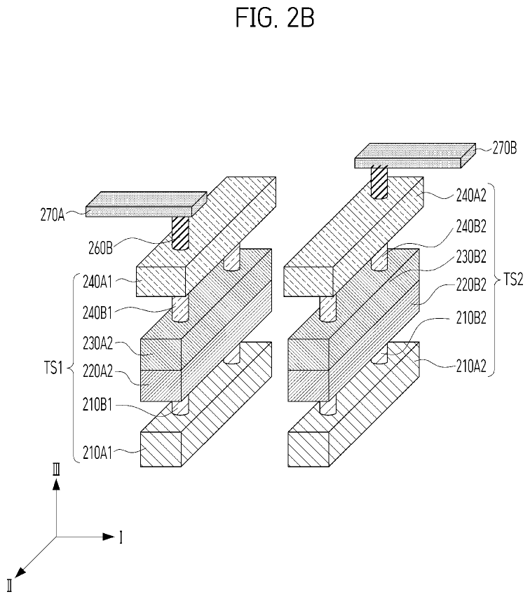

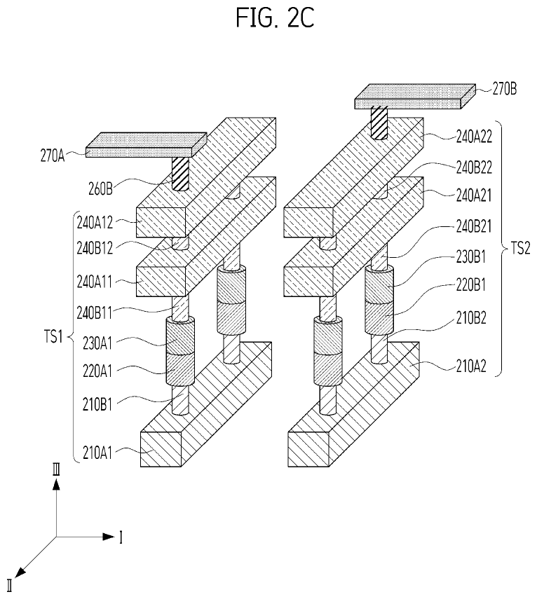

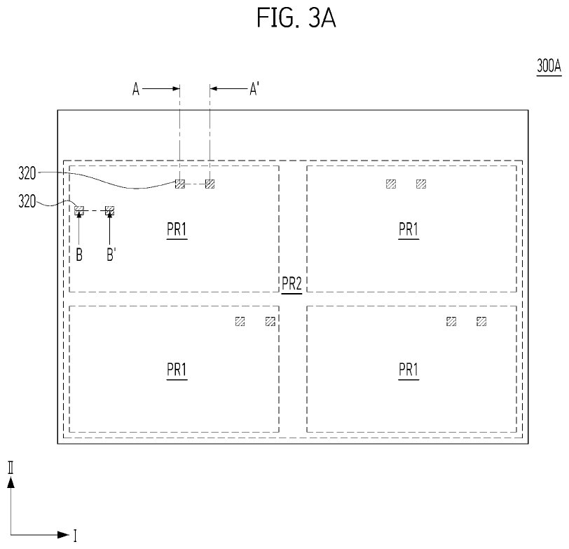

FIGS. 2A to 2C simplified diagrams illustrating a semiconductor device according to an embodiment of the present disclosure. Hereinafter, a content overlapping the content described above is omitted.

Referring to FIG. 2A, the semiconductor device may include at least one of a first test structure TS1, a second test structure TS2, a first probing pad 270A, and a second probing pad 270B.

The first test structure TS1 may include first lower bonding pads 220A1 and first upper bonding pads 230A1 positioned on the first lower bonding pads 220A1. The first test structure TS1 may further include at least one of a first lower test line 210A1, first lower test vias 210B1, a first upper test line 240A1, and first upper test vias 240B1.

The first lower bonding pads 220A1 may be arranged in a second direction II crossing the first direction I. For example, the first lower bonding pads 220A1 may be arranged to be spaced apart in the second direction II. The first lower bonding pads 220A1 may be electrically connected to the first upper bonding pads 230A1. For example, the first lower bonding pads 220A1 may be connected to the first upper bonding pads 230A1, respectively. At least one of the first lower bonding pads 220A1 and the first upper bonding pads 230A1 may include a conductive material such as copper or tungsten.

The first lower test line 210A1 may extend in the second direction II. The first lower test line 210A1 may be connected to the first lower bonding pads 220A1. For example, the first lower test line 210A1 and the first lower bonding pads 220A1 may be connected through the first lower test vias 210B1. For example, the first lower test vias 210B1 may be positioned between the first lower test line 210A1 and the first lower bonding pads 220A1. At least one of the first lower test line 210A1 and the first lower test vias 210B1 may include a conductive material such as copper or tungsten.

The first upper test line 240A1 may extend in the second direction II. The first upper test line 240A1 may be connected to the first upper bonding pads 230A1. For example, the first upper test line 240A1 and the first upper bonding pads 230A1 may be connected through the first upper test vias 240B1. For example, the first upper test vias 240B1 may be positioned between the first upper test line 240A1 and the first upper bonding pads 230A1. At least one of the first upper test line 240A1 and the first upper test vias 240B1 may include a conductive material such as copper or tungsten.

The second test structure TS2 may be positioned adjacent to the first test structure TS1 in the first direction I. The second test structure TS2 may include second lower bonding pads 220B1 and second upper bonding pads 230B1 positioned on the second lower bonding pads 220B1. The second test structure TS2 may further include at least one of a second lower test line 210B1, second lower test vias 210B2, a second upper test line 240A2, and second upper test vias 240B2.

The second lower bonding pads 220B1 may be arranged in the second direction II. The second lower bonding pads 220B1 may be electrically connected to the second upper bonding pads 230B1. At least one of the second lower bonding pads 220B1 and the second upper bonding pads 230B1 may include a conductive material such as copper or tungsten.

The second lower test line 210A2 may extend in the second direction II and may be connected to the second lower bonding pads 220B1. The second lower test line 210A2 and the lower bonding pads 220B1 may be connected through the second lower test vias 210B2. At least one of the second lower test line 210A2 and the second lower test vias 210B2 may include a conductive material such as copper or tungsten.

The second upper test line 240A2 may extend in the second direction II and may be connected to the second upper bonding pads 230B1. The second upper test line 240A2 and the second upper bonding pads 230B1 may be connected through the second upper test vias 240B2. At least one of the second upper test line 240A2 and the second upper test vias 240B2 may include a conductive material such as copper or tungsten.

The probing pads 270A and 270B may be positioned over the bonding pads 220A1, 230A1, 220B1 and 230B1. The probing pads 270A and 270B may extend in the first direction I. The first probing pad 270A may extend in the first direction I and may be electrically connected to the first test structure TS1. The second probing pad 270B may extend in the first direction I and may be electrically connected to the second test structure TS2. For example, the probing pads 270A and 270B and the test structures TS1 and TS2 may be connected through a connection via 260B.

A bonding defect may be detected by applying different voltages to the first probing pad 270A and the second probing pad 270B. For example, the bonding defect may include a bridge that occurs between the bonding pads 220A1, 230A1, 220B1, and 230B1. In other words, a bonding defect may be detected by applying a first voltage to the first probing pad 270A and applying a second voltage different from the first voltage to the second probing pad 270B. For example, the second voltage may be greater than the first voltage.

For example, a ground voltage V_{SS} may be applied to the first probing pad 270A, and an operation voltage V_{cc} may be applied to the second probing pad 270B. For example, the operation voltage V_{cc} may be an external operation voltage. For example, the ground voltage V_{SS} may be 0V, and the operation voltage V_{cc} may be about 3.3V as an external voltage for detecting a bonding defect. A bonding defect may be detected by measuring a breakdown voltage of a pair of probing pads 270A and 270B at a specific current or by measuring a leakage current of at least one of the pair of probing pads 270A and 270B at a specific voltage. When the breakdown voltage is less than a reference voltage or when the leakage current is greater than a reference value, it may be detected that a defect exists in bonding. For example, a voltage of a case where bonding is normal may be the reference voltage, and a leakage current of a case where bonding is normal may be the reference current.

Referring to FIG. 2B, at least one of the first lower bonding pad 220A2 and the second lower bonding pad 220B2 may extend in the second direction II. At least one of the first upper bonding pad 230A2 and the second upper bonding pad 230B2 may extend in the second direction II. In other words, the bonding pads 220A2, 220B2, 230A2, and 230B2 may have a line shape.

The lower bonding pads 220A2 and 220B2 may be connected to the lower test lines 210A1 and 210A2 through the lower test vias 210B1 and 210B2. The upper bonding pads 230A2 and 230B2 may be connected to the upper test lines 240A1 and 240A2 through the upper test vias 240B1 and 240B2.

Referring to FIG. 2C, a plurality of upper test lines 240A11, 240A12, 240A21, and 240A22 and a plurality of upper test vias 240B11, 240B12, 240B21, and 240B22 may be positioned between the upper bonding pads 230A1 and 230B1 and the probing pads 270A and 270B. The upper test lines 240A11 and 240A12 may be connected to each other through the upper test vias 240B11 and 240B12. The upper test lines 240A21 and 240A22 may be connected to each other through the upper test vias 240B21 and 240B22. In an embodiment, a plurality of lower test lines 210A1 and 210A2 and a plurality of lower test vias 210B1 and 210B2 may be positioned under the lower bonding pads 220A1 and 220B1, respectively. In other words, a shape, a connection relationship, and the like of the test lines 210A1, 210A2, 240A11, 240A12, 240A21, and 240A22, the test vias 210B1, 210B2, 240B11, 240B12, 240B21, and 240B22, the bonding pads 220A1, 230A1, 220B1, and 230B1, and the probing pads 270A and 270B are not limited to the embodiment shown in FIG. 2C, but they may be modified, and combined.

According to the structure described above, a bonding defect may be detected by applying different voltages to the probing pads 270A and 270B. In addition, the bonding pads 220A1, 230A1, 220B1, and 230B1 and the probing pads 270A and 270B may be electrically connected through the test lines 210A1, 210A2, 240A11, 240A12, 240A21, and 240A22 and the test vias 210B1, 210B2, 240B11, 240B12, 240B21, and 240B22 of various shapes and combinations.

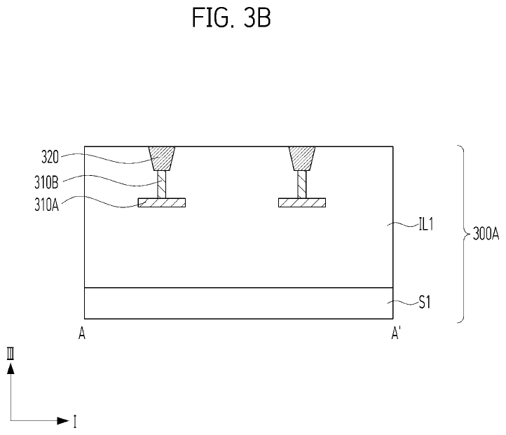

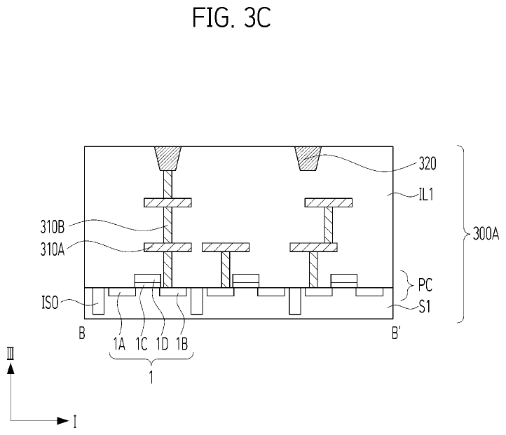

FIGS. 3A to 5C simplified diagrams illustrating a method of manufacturing a semiconductor device according to an embodiment of the present disclosure. FIGS. 3A, 4A, and 5A may be plan views, FIGS. 3B, 4B, and 5B may be cross-sectional views taken along A-A′ of each of FIGS. A, and FIGS. 3C, 4C, and 5C may be cross-sectional views taken along B-B′ of each of FIGS. A. Hereinafter, a content overlapping the content described above is omitted.

Referring to FIGS. 3A to 3C, a first wafer 300A including a first substrate S1 may be formed. The first wafer 300A may include first peripheral circuit regions PR1 and a second peripheral circuit region PR2 between the first peripheral circuit regions PR1. First, the peripheral circuit PC may be formed on the first substrate S1. For example, the peripheral circuit PC may be formed in the first peripheral circuit regions PR1. The peripheral circuit PC may include at least one of the transistor 1, a page buffer, and a decoder. The transistor 1 may include the junctions 1A and 1B, the gate insulating layer 1C, or the gate electrode 1D. An isolation insulating layer ISO may be formed in the first substrate S1, and an active region of the transistor 1 may be defined by the isolation insulating layer ISO.

Subsequently, first bonding pads 320 may be formed on the first substrate S1. At least one of the first bonding pads 320 may be connected to the peripheral circuit PC through first lines 310A and first contact vias 310B. In other words, some of the first bonding pads 320 might not be connected to the peripheral circuit PC. The first bonding pads 320 may include a conductive material such as copper or tungsten. The first bonding pads 320, the first lines 310A, and the first contact vias 310B may be formed in the first interlayer insulating layer IL1. For example, the first interlayer insulating layer IL1 may be formed on the first substrate S1 and may include an insulating material such as oxide.

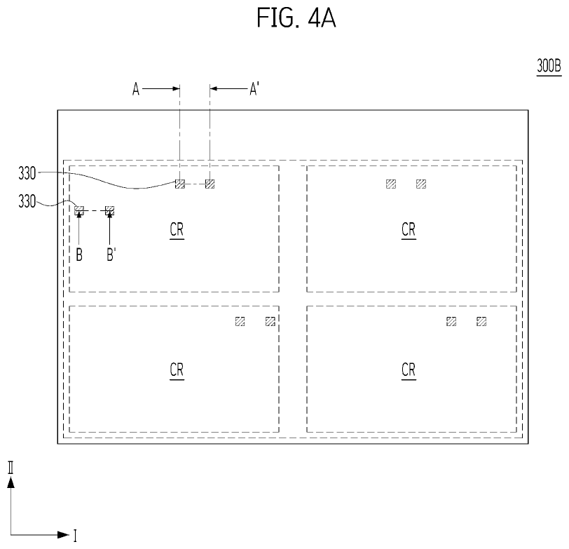

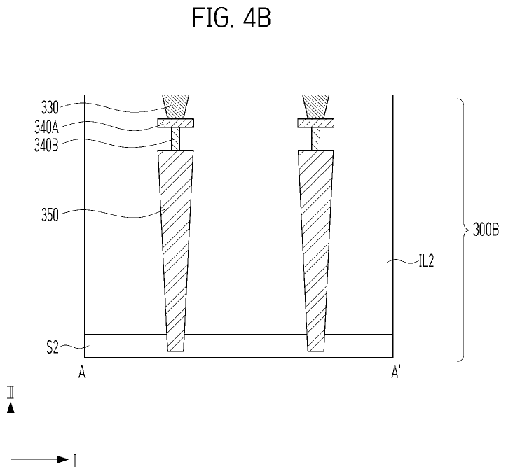

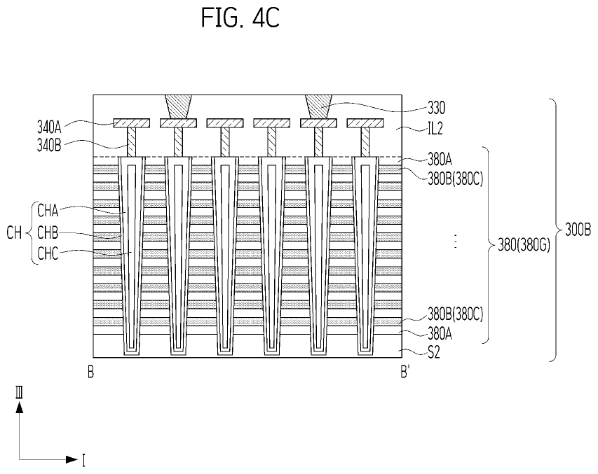

Referring to FIGS. 4A to 4C, a second wafer 300B including a second substrate S2 may be formed. The second wafer 300B may include cell regions CR. First, a stack 380 may be formed by alternately stacking first material layers 380A and second material layers 380B on the second substrate S2. For example, the first material layers 380A may include an insulating material such as oxide, and the second material layers 380B may include a sacrificial material such as nitride. Channel structures CH extending into the second substrate S2 may be formed through the stack 380. The channel structures CH may be formed in the cell region CR of the second substrate S2. Each of the channel structures CH may include at least one of a channel layer CHA, a memory layer 130B surrounding the channel layer 130A, and an insulating core 130C in the channel layer 130A. Subsequently, a slit extending through the stack 380 may be formed, and the second material layers 380B may be replaced with third material layers 380C through the slit. For example, the third material layers 380C may include a conductive material such as tungsten, molybdenum, or polysilicon. Accordingly, a gate structure 380G including the first material layers 380A and the third material layers 380C which are alternately stacked may be formed. For reference, when the second material layers 380B include a conductive material, a replacement process may be omitted. In this case, the stack 380 may be used as the gate structure 380G. Subsequently, a slit structure may be formed by forming an insulating material or a semiconductor material in the slit.

Contact plugs 350 may be formed on the second substrate S2. The contact plugs 350 may extend into the second substrate S2 through the second interlayer insulating layer IL2. The contact plugs 350 may include a conductive material such as tungsten. For example, the second interlayer insulating layer IL2 may be formed on the second substrate S2 and may include an insulating material such as oxide.

Second bonding pads 330 may be formed over the second substrate S2. At least one of the second bonding pads 330 may be connected to the contact plugs 350 through the second lines 340A and the second contact vias 340B. Alternatively, at least one of the second bonding pads 330 may be connected to at least one of the channel structures CH through the second lines 340A and the second contact vias 340B. The second bonding pads 330 may include a conductive material such as copper or tungsten. The second bonding pads 330, the second lines 340A, and the second contact vias 340B may be formed in the second interlayer insulating layer IL2.

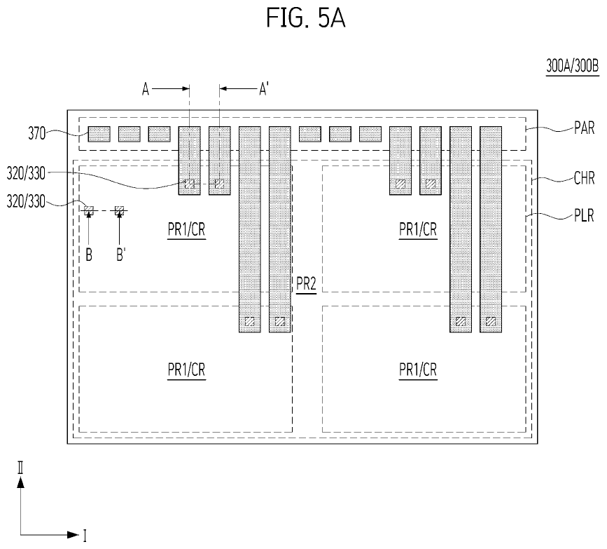

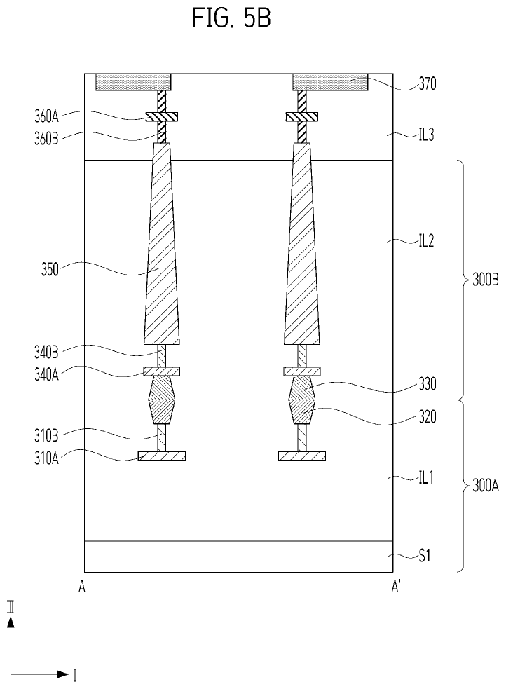

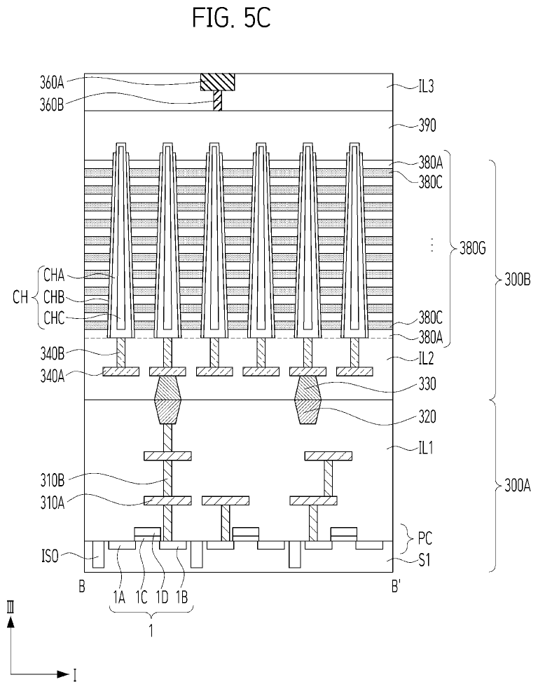

Referring to FIGS. 5A to 5C, the first wafer 300A and the second wafer 300B may be bonded. For example, a front surface of the first bonding pads 320 and a front surface of the second bonding pads 330 may be bonded. The first wafer 300A and the second wafer 300B may be bonded so that the first peripheral circuit regions PR1 of the first wafer 300A and the cell regions CR of the second wafer 300B are stacked.

The bonding pads 320 and 330 may be deteriorated during a process of bonding the first wafer 300A and the second wafer 300B and in a subsequent process. For example, a delamination phenomenon may occur between the first bonding pads 320 and the second bonding pads 330, and copper migration may occur between delaminated positions. Therefore, detecting whether a bonding defect exists by monitoring whether the first bonding pads 320 and the second bonding pads 330 are deteriorated is required.

Subsequently, the second substrate S2 of the second wafer 300B may be removed. Subsequently, a source structure 390 connected to the channel structures CH may be formed on the gate structure 380G. The source structure 390 may include a semiconductor material. Subsequently, the third interlayer insulating layer IL3 may be formed. The third interlayer insulating layer IL3 may be formed on the second interlayer insulating layer IL2. Alternatively, the third interlayer insulating layer IL3 may be formed on the source structure 390.

Subsequently, probing pads 370 may be formed over the bonding pads 320 and 330. At least one of the probing pads 370 may be formed in a region other than a region where the first peripheral circuit region PR1 of the first wafer 300A and the cell region CR of the second wafer 300B are stacked. For example, the probing pads 370 may be formed in the pad region PAR.

The probing pads 370 connected to a rear surface of the second bonding pads 330 may be formed. For example, at least one of the probing pads 370 may extend from the pad region PAR to the chip region CHR and may be connected to the rear surface of the second bonding pads 330. The probing pads 370 may be formed in the third interlayer insulating layer IL3. At least one of the probing pads 370 may be connected to at least one of the contact plugs 350 through third lines 360A and third contact vias 360B. Accordingly, the probing pads 370 and the bonding pads 320 and 330 may be electrically connected. The third lines 360A and the third contact vias 360B may be formed in the third interlayer insulating layer IL3.

A bonding defect may be detected by applying different voltages to a pair of probing pads 370 among the probing pads 370. For example, the bonding defect may include a bridge that occurs between the bonding pads 320 and 330. First, a first voltage may be applied to one of the pair of probing pads 370, and a second voltage greater than the first voltage may be applied to a remaining probing pad 370. For example, the first voltage may be 0V as the ground voltage V_{SS}, and the second voltage may be about 3.3V as an external voltage for detecting a bonding defect, that is, the operation voltage V_{cc}. Subsequently, a breakdown voltage of each of the pair of probing pads 370 may be measured. Alternatively, a leakage current of the remaining probing pad 370 may be measured. For example, the remaining probing pads 370 may refer to a probing pad 370 to which a relatively large voltage is applied. Subsequently, when the breakdown voltage measured through the probing pads 370 is lower than the reference voltage, it may be determined that a defect exists in bonding. Alternatively, when the leakage current measured through the remaining probing pad 370 is higher than the reference current, it may be determined that a defect exists in bonding. For example, the reference voltage or the reference current may refer to a voltage value or a current value when bonding is normal.

Although embodiments according to the scope of the present disclosure have been described with reference to the accompanying drawings, the scope of the present disclosure is not limited to the above-described embodiments and accompanying drawings. It will be apparent to those skilled in the art that various changes and modifications may be made without departing from the scope of the present disclosure.

What is claimed is:

1. A semiconductor device comprising:
a substrate including a chip region and a pad region;
first bonding pads positioned in the chip region;
second bonding pads positioned on the first bonding pads and having a front surface connected to the first bonding pads;
a first probing pad positioned in the pad region, extending to the chip region, and connected to a rear surface of at least one second bonding pad among the second bonding pads; and
a second probing pad positioned neighbor the first probing pad and connected to the rear surface of at least one second bonding pad among the second bonding pads.

2. The semiconductor device of claim 1, wherein a bonding defect is detected by applying a first voltage to the first probing pad and applying a second voltage different from the first voltage to the second probing pad.

3. The semiconductor device of claim 2, wherein the bonding defect includes a bridge occurring between the first bonding pads and the second bonding pads.

4. The semiconductor device of claim 1, wherein the chip region includes a plain region where a peripheral circuit region and a cell region are stacked.

5. The semiconductor device of claim 4, further comprising:
a peripheral circuit positioned in the peripheral circuit region;
a gate structure positioned in the cell region; and
channel structures extending through the gate structure and connected to the peripheral circuit.

6. The semiconductor device of claim 5, further comprising:
a source structure positioned on the gate structure.

7. The semiconductor device of claim 1, wherein at least one of the first bonding pads and the second bonding pads includes copper.

8. A semiconductor device comprising:
a first test structure including a first lower bonding pad and a first upper bonding pad electrically connected to the first lower bonding pad;
a second test structure including a second lower bonding pad and a second upper bonding pad electrically connected to the second lower bonding pad, and positioned neighbor the first test structure in a first direction;
a first probing pad electrically connected to the first test structure and extending in the first direction; and
a second probing pad electrically connected to the second test structure and extending in the first direction.

9. The semiconductor device of claim 8, wherein a ground voltage is applied to the first probing pad and an operation voltage is applied to the second probing pad.

10. The semiconductor device of claim 8, wherein the first test structure comprises:
a first lower test line connected to the first lower bonding pad and extending in a second direction crossing the first direction; and
a first upper test line connected to the first upper bonding pad and extending in the second direction.

11. The semiconductor device of claim 8, wherein the first test structure includes a plurality of first lower bonding pads arranged in a second direction crossing the first direction.

12. The semiconductor device of claim 8, wherein the first test structure includes a plurality of first upper bonding pads arranged in a second direction crossing the first direction.

13. The semiconductor device of claim 8, wherein at least one of the first lower bonding pad and the second lower bonding pad extends in a second direction crossing the first direction.

14. The semiconductor device of claim 8, wherein at least one of the first upper bonding pad and the second upper bonding pad extends in a second direction crossing the first direction.

15. The semiconductor device of claim 8, wherein the second test structure comprises:
a second lower test line connected to the second lower bonding pad and extending in a second direction crossing the first direction; and
a second upper test line connected to the second upper bonding pad and extending in the second direction.

16. The semiconductor device of claim 8, wherein the second test structure includes a plurality of second lower bonding pads arranged in a second direction crossing the first direction.

17. The semiconductor device of claim 8, wherein the second test structure includes a plurality of second upper bonding pads arranged in a second direction crossing the first direction.

18. A method of manufacturing a semiconductor device, the method comprising:
forming a first wafer including a first substrate and first bonding pads;
forming a second wafer including a second substrate and second bonding pads;
bonding the first wafer and the second wafer so that a front surface of the first bonding pads and a front surface of the second bonding pads are connected;
forming probing pads respectively connected to rear surfaces of the second bonding pads; and
detecting a bonding defect by applying different voltages to a pair of probing pads among the probing pads.

19. The method of claim 18, wherein detecting the bonding defect comprises:
applying a first voltage to one of the pair of probing pads and applying a second voltage greater than the first voltage to a remaining probing pad; and
measuring a breakdown voltage of the pair of probing pads.

20. The method of claim 19, wherein the bonding defect exists when the breakdown voltage is lower than a reference voltage.

21. The method of claim 18, wherein detecting the bonding defect comprises:
applying a first voltage to one of the pair of probing pads;
applying a second voltage greater than the first voltage to a remaining probing pad; and
measuring a leakage current of the remaining probing pad.

22. The method of claim 21, wherein the bonding defect exists when the leakage current is higher than a reference current.

23. The method of claim 18, wherein the first wafer includes a peripheral circuit region, the second wafer includes a cell region, and the first wafer and the second wafer are bonded so that the peripheral circuit region and the cell region are stacked.

24. The method of claim 23, wherein the peripheral circuit region includes a peripheral circuit, and
wherein the cell region includes a stack and channel structures extending through the stack.

25. The method of claim 24, further comprising:
removing the second substrate, after the bonding; and
forming a source structure connected to the channel structures.

26. The method of claim 23, wherein the probing pads are formed in a pad region, and the pad region is a region spaced apart from the peripheral circuit region and the cell region.

27. The method of claim 26, wherein the probing pads extend from the pad region and are respectively connected to rear surfaces of the second bonding pads.

28. The method of claim 18, wherein the first bonding pads or the second bonding pads include copper.
